(19) United States
(12) Patent Application Publication
(10) Pub. No.: US 2008/0237821 A1
(43) Pub. Date: Oct. 2, 2008

(54) Package structure and manufacturing method thereof

(75) Inventors: Hyeongno Kim, Paju-si (KR); Soo-Min Choi, Paju-si (KR); Jae-Sun An, Paju-si (KR); Young-Gue Lee, Paju-si (KR); Sang-Jin Cha, Paju-si (KR)

Correspondence Address: BIRCH STEWART KOLASCH & BIRCH, PO BOX 747, FALLS CHURCH, VA, 22040-0747, US

(73) Assignee: Advanced Semiconductor Engineering, Inc.

(21) Appl. No.: 11/727,796

(22) Filed: Mar. 28, 2007

(51) Int. Cl. H01L 23/02

(52) U.S. Cl. 257/678

(57) ABSTRACT

A package structure and a manufacturing method thereof are provided. The package structure includes a substrate, a shielding plate, a first chip, a first sealant, a second chip and a second sealant. The substrate has a lower surface and an upper surface on which the shielding plate is disposed. The first chip disposed on the shielding plate is electrically connected to the substrate. The first sealant disposed on the upper surface encapsulates the shielding plate and the first chip. The second chip disposed on the lower surface is electrically connected to the substrate. The second sealant disposed on the lower surface encapsulates the second chip.

### BACKGROUND OF THE INVENTION

1. Field of the Invention

The invention relates in general to a package structure and a manufacturing method thereof, and more particularly to a package structure with several chips and a manufacturing method thereof.

2. Description of the Related Art

Recently, consumer electronics with less weight and smaller volume are developed to meet the market demands. Within the limited spaced of an electronic product, more semiconductor devices with various functions and more complex circuits need to be disposed to enhance the functionality of the electronic product. Normally, in the packaging process of the semiconductor device, a semiconductor chip is disposed on a substrate and electrically connected to the substrate through a wire-bonding process, a flip-chip process or other bonding processes subsequently, so that the inner microelectronic circuit can be electrically connected to the outer circuit through the contacts or pads on the substrate. However, along with the increment of the complexity of semiconductor chips, the number of electric contacts or pads increases accordingly. Thus the area of the substrate, in accordance with the volume of the semiconductor device, cannot be reduced effectively. In order to break the spatial limitation, a semiconductor device with multi-chip package structure is developed for applying in all kinds of integrated and multifunctional electronic products. In the semiconductor device with multi-chip package structure, different semiconductor chips are disposed and integrally packaged in a single package structure. As a result, the number of semiconductor devices in an electronic product can be reduced, and the space in the electronic product can be used more efficiently.

Nevertheless, during operation of the semiconductor device, electromagnetic radiation is inevitably generated when each semiconductor chip functions. Along with the miniature of the semiconductor device, the semiconductor chips in the multi-chip package structure keep a reduced distance compared to that in the traditional single-chip package structure. The interference between the semiconductor chips increases consequently. As a result, noise is raised, and the operation quality of the chips is degraded. These drawbacks hinder the semiconductor device from further reducing its size, and cause the overall quality of the electronic product not being guaranteed.

### SUMMARY OF THE INVENTION

The invention is directed to a package structure and a manufacturing method thereof. A shielding plate is disposed between a first chip and a second chip for lowering the electromagnetic interference between the first chip and the second chip. As a result, the package structure has advantages such as high stability, high quality, small volume and low developing cost.

According to the present invention, a package structure including a substrate, a shielding plate, a first chip, a first sealant, a second chip and a second sealant is provided. The substrate has an upper surface and a lower surface. The shielding plate is disposed on the upper surface. The first chip disposed on the shielding plate is electrically connected to the substrate. The first sealant disposed on the upper surface encapsulates the shielding plate and the first chip. The second chip disposed on the lower surface is electrically connected to the substrate. The second sealant disposed on the lower surface encapsulates the second chip.

According to the present invention, another package structure including a package, a shielding plate, a supporting element, a second chip and a first sealant is provided. The package includes a first chip and a substrate to which the first chip is electrically connected. The shielding plate is disposed over the package. The supporting element is disposed under the shielding plate. The second chip is dispose on the shielding plate and electrically connected to the substrate. The first sealant disposed on the substrate encapsulates the shielding plate and the second chip.

The invention will become apparent from the following detailed description of the preferred but non-limiting embodiments. The following description is made with reference to the accompanying drawings.

### BRIEF DESCRIPTION OF THE DRAWINGS

FIG. 1A illustrates a substrate according to a first embodiment of the invention;

FIG. 1B illustrates a shielding plate disposed on the substrate in FIG. 1A;

FIG. 1C illustrates a first chip disposed on the shielding plate in FIG. 1B;

FIG. 1D illustrates a first sealant disposed on the substrate in FIG. 1C;

FIG. 1E illustrates a second chip disposed on a lower surface of the substrate in FIG. 1D;

FIG. 1F illustrates a second sealant disposed on the lower surface of the substrate in FIG. 1E;

FIG. 1G illustrates a solder ball disposed on the lower surface of the substrate in FIG. 1F;

FIG. 2 illustrates the shielding plate including several material layers;

FIG. 3 illustrates the solder ball including several materials;

FIG. 4A illustrates a package according to a second embodiment of the invention;

FIG. 4B illustrates a supporting element disposed on the package in FIG. 4A;

FIG. 4C illustrates a shielding plate disposed on the supporting element in FIG. 4B;

FIG. 4D illustrates a second chip disposed on the shielding plate in FIG. 4C;

FIG. 4E illustrates a first sealant disposed on the substrate in FIG. 4D;

FIG. 4F illustrates a solder ball disposed on a lower surface of the substrate in FIG. 4E;

FIG. 4G illustrates a package structure with a dummy die used as the supporting element;

FIG. 5A illustrates a substrate according to a third embodiment of the invention;

FIG. 5B illustrates an adhesive film disposed on a lower surface of the substrate in FIG. 5A;

FIG. 5C illustrates a first chip adhered to the adhesive film in FIG. 5B;

FIG. 5D illustrates the supporting element disposed in the package structure in FIG. 5C;

FIG. 5E illustrates the package structure according to the third embodiment of the invention; and

FIG. 6 illustrates a package structure according to a fourth embodiment of the invention.

### DETAILED DESCRIPTION OF THE INVENTION

Four embodiments are provided as follow to illustrate the present invention. The embodiments are different in the arrangement of the components in the package structure. However, the embodiments are used as examples, and the present invention is not limited thereto. Also, the embodiments are encompassed by the present invention. Furthermore, unnecessary components are not shown in the drawings for clarity.

### First Embodiment

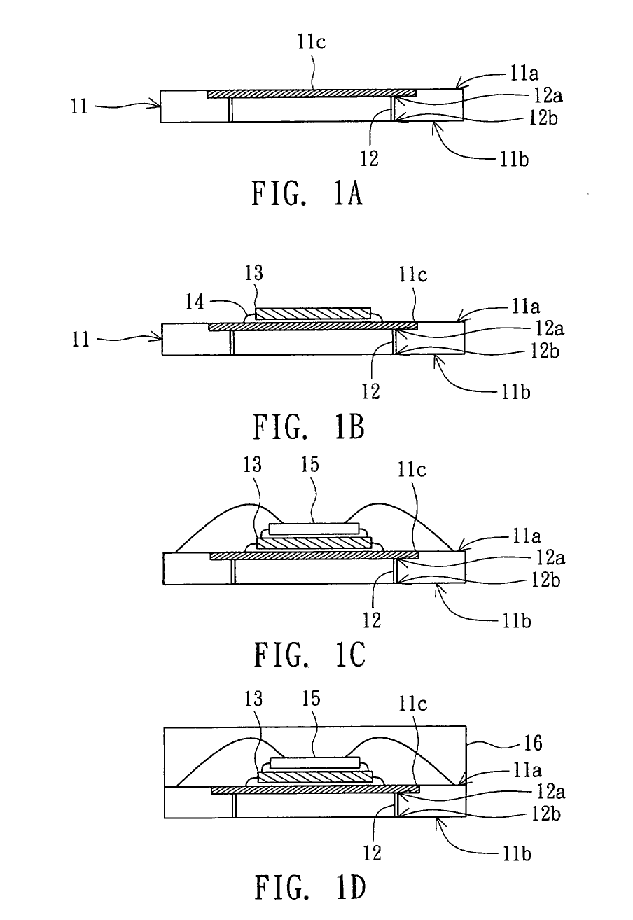

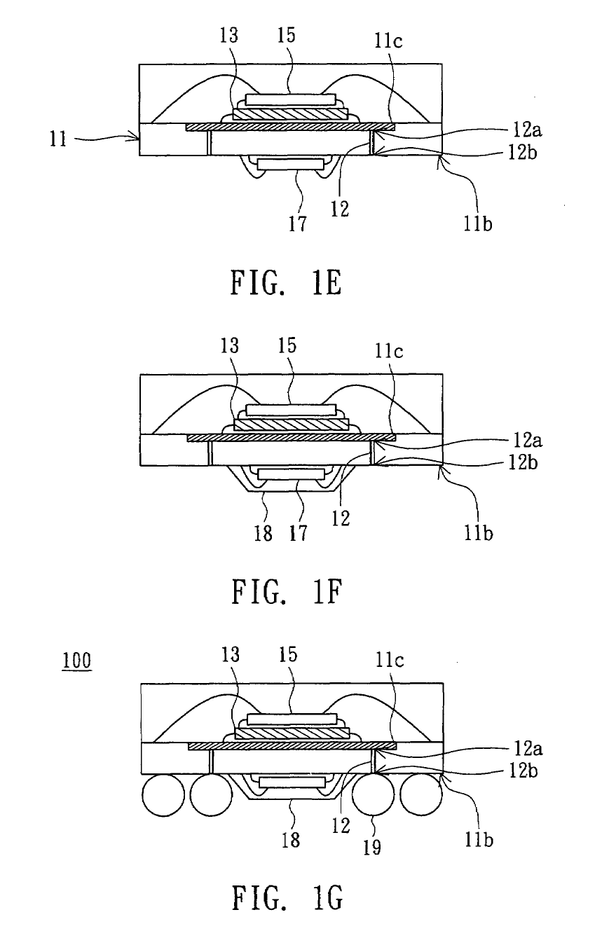

Please refer to FIGS. 1A˜1G at the same time. FIG. 1A illustrates a substrate according to a first embodiment of the invention. FIG. 1B illustrates a shielding plate disposed on the substrate in FIG. 1A. FIG. 1C illustrates a first chip disposed on the shielding plate in FIG. 1B. FIG. 1D illustrates a first sealant disposed on the substrate in FIG. 1C. FIG. 1E illustrates a second chip disposed on a lower surface of the substrate in FIG. 1D. FIG. 1F illustrates a second sealant disposed on the lower surface of the substrate in FIG. 1E. FIG. 1G illustrates a solder ball disposed on the lower surface of the substrate in FIG. 1F. A manufacturing method of a package structure according to the first embodiment of the invention includes following steps. First, a substrate 11 having an upper surface 11a, a lower surface 11b and a contact pad 11c is provided, as shown in FIG. 1A. The contact pad 11c is located on the upper surface 11a, and is exemplified by a rectangular, circular or spiral flat plate.

Next, as shown in FIG. 1B, a shielding plate 13 is disposed on the upper surface 11a. In the present embodiment, the shielding plate 13 is connected to the contact pad 11c preferably through a conductive adhesive 14, for electrically connecting the shielding plate 13 and the contact pad 11c.

Then, a first chip 15 is disposed on the shielding plate 13 and is electrically connected to the substrate 11 through wire bonding, as shown in FIG. 1C.

Afterwards, as shown in FIG. 1D, a first sealant 16 encapsulating the shielding plate 13 and the first chip 15 is disposed on the upper surface 11a.

Further, a second chip 17 is disposed on the lower surface 11b and electrically connected to the substrate 11 through wire bonding, as shown in FIG. 1E.

Thereon, as shown in FIG. 1F, a second sealant 18 encapsulating the second chip 17 is disposed on the lower surface 11b. Preferably, the second sealant 18 encapsulates only a portion of the lower surface 11b.

Furthermore, a solder ball 19 is disposed on the lower surface 11b. As shown in FIG. 1G, the substrate 11 includes a conductive trace 12 penetrating the substrate 11. The conductive trace 12 has a first end 12a and a second end 12b. The first end 12a is connected to the contact pad 11c. The second end 12b is connected to the solder ball 19. After the solder ball 19 is disposed on the lower surface 11b of the substrate 11, the package structure 100 according to the first embodiment of the invention is accomplished.

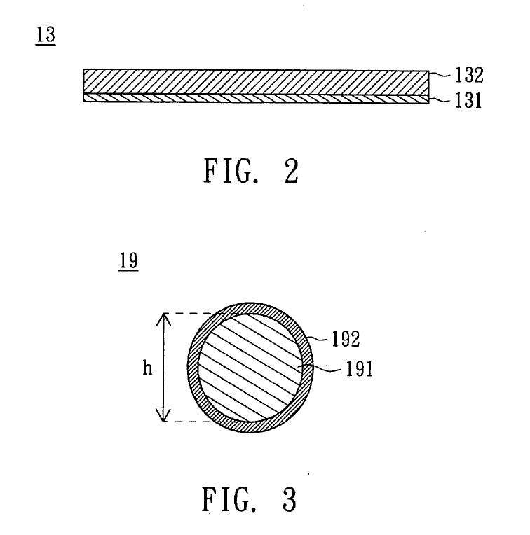

Moreover, the shielding plate 13 in the present embodiment includes several holes or is provided with a spiral structure for example. The area of the shielding plate 13 is preferably greater than that of the first chip 15 and the second chip 17. On the other hand, the shielding plate 13 is made of single conductive material or includes several material layers. Please referring to FIG. 2 at the same time, the shielding plate including several material layers is illustrated in FIG. 2. The shielding plate 13 includes a conductive layer 131 and a non-conductive layer 132. Besides, the first end 12a of the conductive trace 12 is electrically connected to the contact pad 11c. The second end 12b of the conductive trace 12 is electrically connected to the solder ball 19. For example, the solder ball 19 is a grounding ball. The shielding plate 13 is preferably electrically conductive material and is electrically connected to a ground plane through the contact pad 11c, the conductive trace 12 and the solder ball 19.

Please referring to FIG. 3 at the same time, the solder ball including several materials is illustrated in FIG. 3. The solder ball 19 is preferably includes a first material 191 having a first melting point and a second material 192 having a second melting point. The second material 192 encapsulates the first material 191, and the first melting point is higher than the second melting point. While disposing the solder ball 19 onto the lower surface 11b, the solder ball 19 is heated to reach the second melting point, so that the second material 192 is melted. Due to the first material 191 remaining solid at this moment, the solder ball 19 has at least a height h of the first material 191. Therefore, when the package structure 100 is bonded to an outer device (not shown in drawings) through the solder ball 19, the package structure 100 is disposed at a distance from the outer device. As a result, the outer device does not contact the second sealant 18.

In the package structure and the manufacturing method thereof according to the first embodiment of the invention, the shielding plate 13 is disposed on the upper surface 11a of the substrate 11. Also, the first chip 15 is disposed on the shielding plate 13, and the second chip 17 is disposed on the lower surface 11b of the substrate 11. In other words, the shielding plate 13 is located between the first chip 15 and the second chip 17. Furthermore, the shielding plate 13 is electrically connected to a ground plane through the contact pad 11c, the conductive trace 12 and the solder ball 19. When the package structure 100 functions, the shielding plate 13 shields the first chip 15 and the second chip 17. The two chips are prevented from interfering with each other, so that the operation accuracy of the chips is increased. The stability of the product is increased greatly.

### Second Embodiment

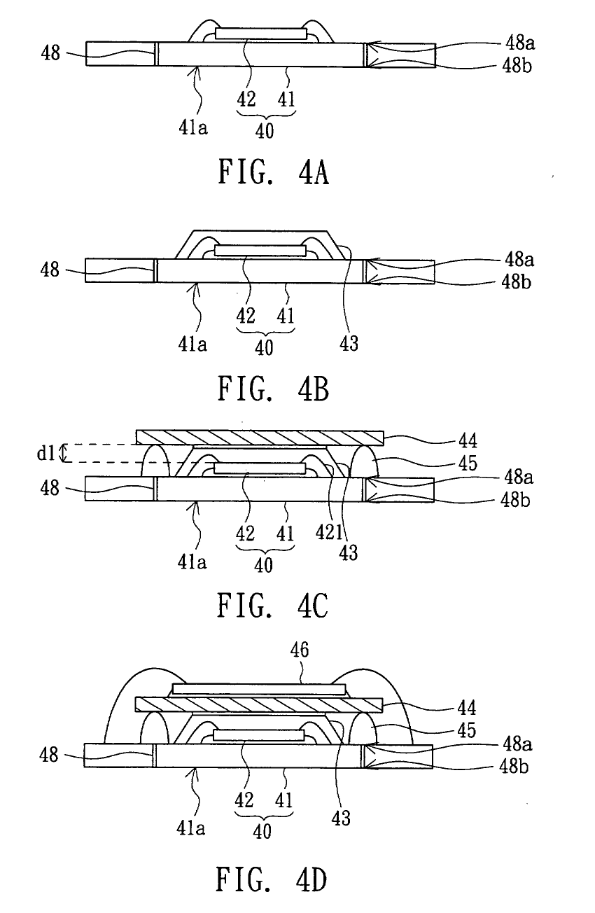

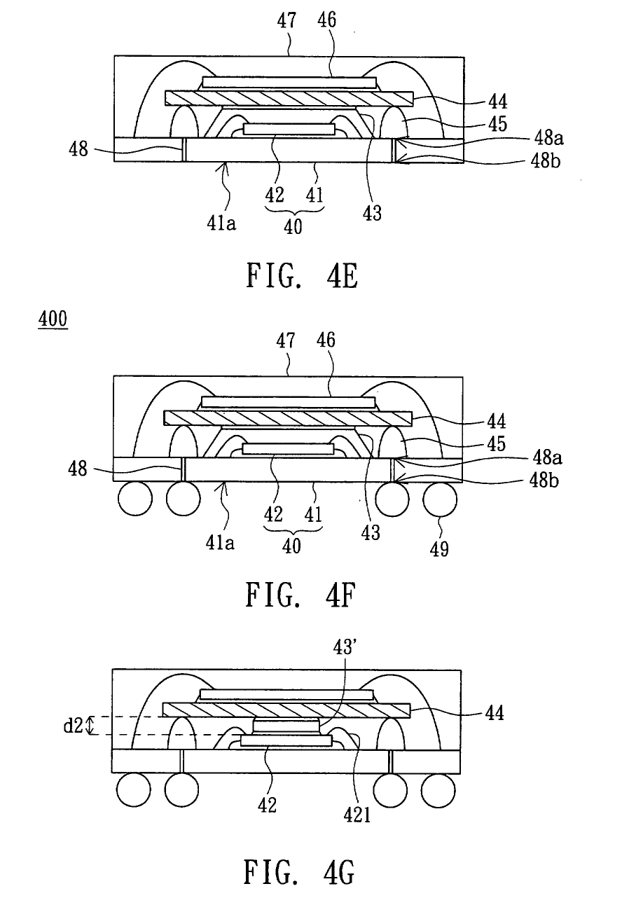

Please refer to FIGS. 4A˜4F at the same time. FIG. 4A illustrates a package according to a second embodiment of the invention. FIG. 4B illustrates a supporting element disposed on the package in FIG. 4A. FIG. 4C illustrates a shielding plate disposed on the supporting element in FIG. 4B. FIG. 4D illustrates a second chip disposed on the shielding plate in FIG. 4C. FIG. 4E illustrates a first sealant disposed on the substrate in FIG. 4D. FIG. 4F illustrates a solder ball disposed on a lower surface of the substrate in FIG. 4E. A manufacturing method of a package structure according to the second embodiment of the invention includes following steps. First, a package 40 including a substrate 41 and a first chip 42 is provided. The first chip 42 is electrically connected to the substrate 41 through wire bonding, as shown in FIG. 4A.

Next, as shown in FIG. 4B, a supporting element 43 is disposed on the package 40. In the present embodiment, the supporting element 43 is a second sealant for example. The supporting element 43 is disposed through following steps. First, the second sealant encapsulating the first chip 42 is disposed on the substrate 41. Then, the second sealant is solidified.

Afterwards, a shielding plate 44 is disposed on the supporting element 43, as shown in FIG. 4C. The shielding plate 44 is disposed at a distance from the first chip 42 due to the supporting element 43. Therefore, the shielding plate 44 does not contact a gold wire 421 of the first chip 42 to avoid short circuit. The gold wire 421 is used for wire bonding the first chip 42 and the substrate 41. Moreover, the substrate 41 further includes a conductive trace 48 penetrating the substrate 41. The conductive trace 48 has a first end 48a and a second end 48b. The first end 48a is connected to the shielding plate 44 through a conductive element 45 that is a conductive adhesive or a conductive metal ball for example.

Thereon, as shown in FIG. 4D, a second chip 46 is disposed on the shielding plate 44 and electrically connected to the substrate 41 through wire bonding. The area of the shielding plate 44 is preferably greater than that of the first chip 42 and the second chip 46.

Subsequently, a first sealant 47 encapsulating the shielding plate 44, the second chip 46 and the supporting element 43 is disposed on the substrate 41, as shown in FIG. 4E.

After, as shown in FIG. 4F, a solder ball 49 is disposed on a lower surface 41a of the substrate 41. The second end 48b of the conductive trace 48 is connected to the solder ball 49. After the solder ball 49 is disposed, the package structure 400 according to the second embodiment of the invention is accomplished.

In the present embodiment, the supporting element 43 is exemplified by the second sealant. However, anyone who has ordinary skill in the field of the invention can understand that the invention is not limited thereto. The supporting element 43 can be any object that separates the shielding plate 44 and the first chip 42. Please referring to FIG. 4G, a package structure with a dummy die used as the supporting element is illustrated in FIG. 4G. The dummy die 43′ is disposed between the shielding plate 44 and the first chip 42, so that the shielding plate 44 is disposed at a distance d2 from the first chip 42. As a result, the shielding plate 44 does not contact the gold wire 421.

Besides, the first end 48a of the conductive trace 48 is electrically connected to the shielding plate 44 through the conductive element 45. The second end 48b of the conductive trace 48 is electrically connected to the solder ball 49. For example, the solder ball 49 is a grounding ball. The shielding plate 44 is preferably electrically conductive material and is electrically connected to a ground plane through the conductive element 45, the conductive trace 48 and the solder ball 49.

Furthermore, the materials of the shielding plate 44 and the solder ball 49 in the present embodiment are the same as those in the first embodiment of the invention and not described repeatedly. For example, the shielding plate 44 and the solder ball 49 includes several materials (as shown in FIG. 2 and FIG. 3).

### Third Embodiment

The package structure in the present embodiment and the package structure 400 in the second embodiment (as shown in FIG. 4F) are different in the relative positions of the first chip and the substrate. The same parts are not described repeatedly.

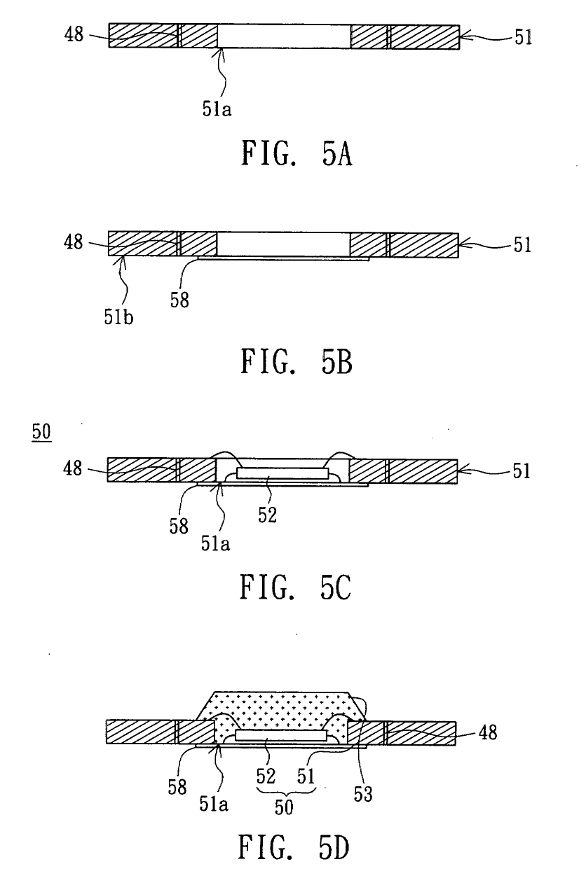

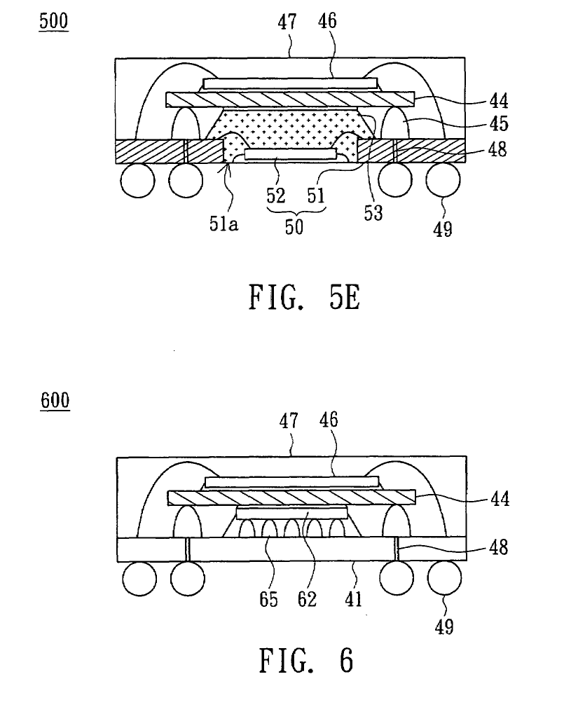

In the present embodiment, the step of providing the package further includes following steps. Please refer to FIGS. 5A˜5C at the same time. FIG. 5A illustrates a substrate according to the third embodiment of the invention. FIG. 5B illustrates an adhesive film disposed on a lower surface of the substrate in FIG. 5A. FIG. 5C illustrates a first chip adhered to the adhesive film in FIG. 5B. First, as shown in FIG. 5A, a substrate 51 with an opening 51a is provided. Next, as shown in FIG. 5B, an adhesive film 58 is provided on a lower surface 51b of the substrate 51. The area of the adhesive film 58 is greater than that of the opening 51a. Then, as shown in FIG. 5C, a first chip 52 is adhered to the adhesive film 58 and wire-bonded to the substrate 51, so that the first chip 52 is disposed in the opening 51a. The wire-bonded substrate 51 and first chip 52 is the package 50.

The manufacturing method of the package structure in the present embodiment further performs the step of disposing a supporting element. Please referring to FIG. 5D at the same time, the supporting element disposed in the package structure in FIG. 5C is illustrated in FIG. 5D. The supporting element 53 is exemplified by a second sealant. The step of disposing the supporting element 53 further includes following steps. First, the second sealant encapsulating the first chip 52 is disposed in the opening 51a and on the substrate 51. Then, the second sealant is solidified so as to form the supporting element 53.

Afterwards, the adhesive film 58 is removed. Then, the steps of disposing the shielding plate, the second chip and first sealant are preformed. The steps of disposing the shielding plate, the second chip and first sealant in the present embodiment are the same as those in the second embodiment of the invention and not described repeatedly.

After the first sealant 47 is disposed on the substrate 51, the package structure 500 according to the third embodiment of the invention is accomplished. Please referring to FIG. 5E, the package structure according to the third embodiment of the invention is illustrated in FIG. 5E. The package structure 500 includes the package 50, the shielding plate 44, the supporting element 53, the second chip 46, the first sealant 47, the conductive trace 48 and the solder ball 49. In the package structure 500, the first chip 52 is disposed in the opening 51a of the substrate 51, so that the height of the package structure 500 is reduced. Furthermore, the volume of the package structure 500 is decreased.

### Fourth Embodiment

Please referring FIG. 6, a package structure according to a fourth embodiment of the invention is illustrated in FIG. 6. The package structure 600 includes a substrate 41, a first chip 62, a shielding plate 44, a second chip 46, a sealant 47, a conductive trace 48 and a solder ball 49. The difference between the package structure 600 of the present embodiment and the package structure 400 of the second embodiment (as shown in FIG. 4F) is that the first chip 62 is disposed on the substrate 41 by flip-chip bonding in the present embodiment. The same parts are not described repeatedly.

Because the first chip 62 is disposed on the substrate 41 by flip-chip bonding and is electrically connected to the substrate 41 through several contacts 65 under the first chip 62, the shielding plate 44 may dispose on the first chip 62 directly; thus lowering both the cost and the volume of the package structure 600.

In the package structure and the manufacturing method thereof according to above embodiments of the invention, the shielding plate is disposed between the first chip and the second chip. As a result, the first chip and the second chip are shielded by the shielding plate, so that the two chips do not interfere with each other while operating. Further, the operation stability of the chips and the quality of the product are guaranteed. Besides that, the package structures according to the above embodiments of the invention can be manufactured simply by adding a shielding plate between the chips in the conventional package structures. That is, the manufacturing method of the package structure according to the embodiments of the invention is compatible with the conventional manufacturing method. Therefore, the cost for developing a new manufacturing process can be saved. Moreover, due to the shield of the shielding plate, the distance between the two chips can be further reduced, and the volume of the package structure can be decreased accordingly.

While the invention has been described by way of example and in terms of preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A package structure comprising:
a substrate having an upper surface and a lower surface;
a shielding plate disposed on the upper surface;
a first chip disposed on the shielding plate and electrically connected to the substrate;
a first sealant disposed on the upper surface and encapsulating the shielding plate and the first chip;
a second chip disposed on the lower surface and electrically connected to the substrate; and
a second sealant disposed on the lower surface and encapsulating the second chip.

2. The package structure according to claim 1, wherein the substrate comprises a contact pad disposed on the upper surface the shielding plate connected to the contact pad.

3. The package structure according to claim 2, wherein the contact pad is a rectangular, circular or spiral flat plate.

4. The package structure according to claim 1 further comprising:
a conductive trace disposed in the substrate and having a first end and a second end, the first end electrically connected to the shielding plate; and
a solder ball disposed on the lower surface, the second end connected to the solder ball.

5. The package structure according to claim 4, wherein the solder ball is a grounding ball, the shielding plate being electrically conductive material, the shielding plate electrically connected to a ground plane through the conductive trace and the solder ball.

6. The package structure according to claim 4, wherein the solder ball comprises:
a first material having a first melting point; and
a second material encapsulating the first material and having a second melting point;
wherein the first melting point is higher than the second melting point.

7. The package structure according to claim 1, wherein the shielding plate further comprising a plurality of holes.

8. The package structure according to claim 1, wherein the shielding plate is a spiral structure.

9. A package structure comprising:
a package comprising:
a substrate; and
a first chip electrically connected to the substrate;
a shielding plate disposed over the package;
a supporting element disposed under the shielding plate
a second chip disposed on the shielding plate and electrically connecting to the substrate; and
a first sealant disposed on the substrate and encapsulating the shielding plate and the second chip.

10. The package structure according to claim 9, wherein the first chip is wire-bonded to the substrate.

11. The package structure according to claim 9, wherein the supporting Hi element is a dummy die disposed between the first chip and the shielding plate, and the first sealant further encapsulates the dummy die.

12. The package structure according to claim 9, wherein the supporting element is a second sealant disposed between the shielding plate and the substrate, and the first sealant further encapsulates the second sealant.

13. The package structure according to claim 9, wherein the substrate further comprising an opening, the first chip disposed in the opening.

14. The package structure according to claim 13, wherein the supporting element is a second sealant disposed in the opening and between the shielding plate and the substrate, and the first sealant encapsulates the second sealant.

15. The package structure according to claim 9 further comprising:
a conductive trace disposed in the substrate and having a first end and a second end, the first end connected to the shielding plate through a conductive element; and
a solder ball disposed on a lower surface of the substrate, the second end connected to the solder ball.

16. The package structure according to claim 15, wherein the solder ball is a grounding ball, the shielding plate being electrically conductive material and electrically connected to a ground plane through the conductive element, the conductive trace and the solder ball.

17. The package structure according to claim 15, wherein the solder ball comprising:
a first material having a first melting point; and
a second material having a second melting point;
wherein the first melting point is higher than the second melting point.

18. The package structure according to claim 15, wherein the conductive element is selected from a group of a conductive adhesive and a conductive metal ball.

19. The package structure according to claim 9, wherein the shielding plate comprising a plurality of holes.

20. The package structure according to claim 9, wherein the shielding plate is a spiral structure.
